(19) United States
(12) Patent Application Publication
(10) Pub. No.: US 2006/0284305 A1
(43) Pub. Date: Dec. 21, 2006

(54) Packaging base for semiconductor elements

(76) Inventors: Hsien-Cheng Yen, Dashi (TW); Hung-Sheng Lee, Dashi (TW); Ming-Cho Wu, Dashi (TW); Szutsun-Simon Ou, Dashi (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/450,552

(22) Filed: Jun. 12, 2006

(30) Foreign Application Priority Data
Jun. 17, 2005 (TW) 094210172

(51) Int. Cl. H01L 23/14

(52) U.S. Cl. 257/708; 257/713; 257/99; 257/711

(57) ABSTRACT

A packaging base for semiconductor elements is made of metal powder selected from the group consisting of cupper (Cu), iron (Fe), wolfram (W), molybdenum (Mo), aluminum (Al), indium (In), and gallium (Ga) or from an alloy of combinations thereof. A heat sink is integrally formed by metallurgical injection molding process. A fixing mount and a protection mount are positioned on the heat sink, thereby creating a packaging base structure. The protection mount surrounds the fixing mount for protecting semiconductor elements like laser diode dies. The packaging base structure includes a mounting gap for the purpose of an easy installation of the semiconductor elements. In this way, the reduction of the heat-removal capacity caused by the thermal contact resistance of the conventional configuration can be avoided so that the cooling effect can be enhanced. Meanwhile, the fabrication process is simplified.

### BACKGROUND OF THE INVENTION

1. Field of the Invention

The invention relates to a packaging base for semiconductor elements, and more particularly to a base that is made of metal powder by metallurgical injection molding process and integrally formed.

2. Description of the Related Art

In designing the packaging configuration of the semiconductor elements, the heat-removal property must be taken into account. As shown in FIGS. 1 and 2, a laser diode packaging structure includes a heat sink 10 on which a mount 11 is disposed. The laser diode die 20 is fixed on the mount 11. In protecting the laser diode die 20 from damage due to the application of external force, a cover 30 is placed on the mount 11. The high temperature created by the laser diode during its operation will be removed by the heat sink 10 for ensuring a smooth operation of the laser diode.

The heat sink 10 and mount 11 of the conventional laser diode are separately made by the punching process and then welded together. In this way, a thermal contact resistance that reduces the heat-removal capacity is created between the heat sink 10 and the mount 11. Moreover, a welding process is necessarily required.

### SUMMARY OF THE INVENTION

A primary object of the invention is to provide a packaging base for semiconductor elements that avoids the reduction of the heat-removal capacity caused by the thermal contact resistance of the conventional configuration and, therefore, increases the cooling effect.

Another object of the invention is to provide a packaging base for semiconductor elements that simplifies the fabrication process.

In order to achieve the above-mentioned objects, a packaging base for semiconductor elements in accordance with the invention is made of metal powder selected from the group consisting of cupper (Cu), iron (Fe), tungsten (W), molybdenum (Mo), aluminum (Al), indium (In), and gallium (Ga) or from an alloy of combinations thereof. A heat sink is integrally formed by metallurgical injection molding process. A fixing mount and a protection mount are positioned on the heat sink, thereby creating a packaging base structure. The protection mount surrounds the fixing mount for protecting semiconductor elements like laser diode dies. The packaging base structure includes a mounting gap for the purpose of an easy installation of the semiconductor elements.

By use of integral forming, the process of assembly of all elements can be saved. Meanwhile, it is avoidable to produce the thermal contact resistance.

### BRIEF DESCRIPTION OF THE FIGURES

The accomplishment of this and other objects of the invention will become apparent from the following descriptions and its accompanying figures of which:

FIG. 1 is a perspective view of a conventional laser diode structure;

FIG. 2 is a cutaway view of the conventional laser diode structure; FIG. 3 is a perspective view of a packaging base for semiconductor elements in accordance with the invention; and

FIG. 4 is a cutaway view of the packaging base for semiconductor elements in accordance with the invention.

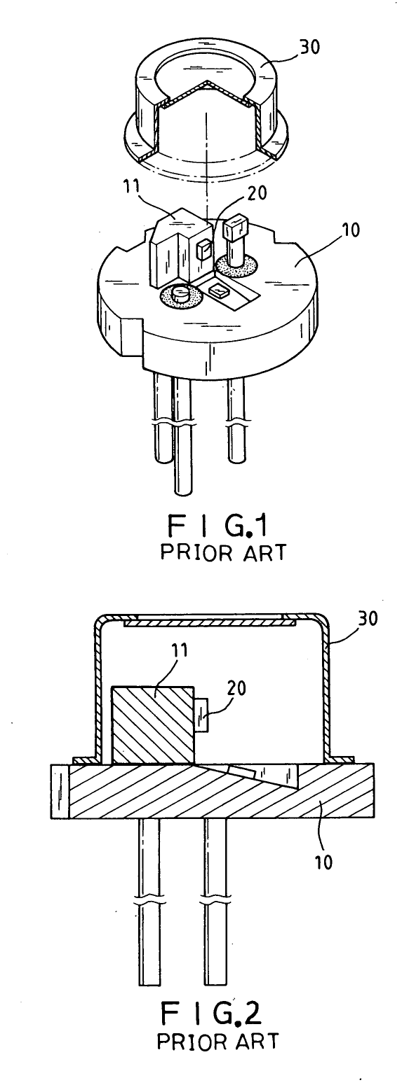

### DETAILED DESCRIPTION OF THE PREFERRED EMBODIMENT

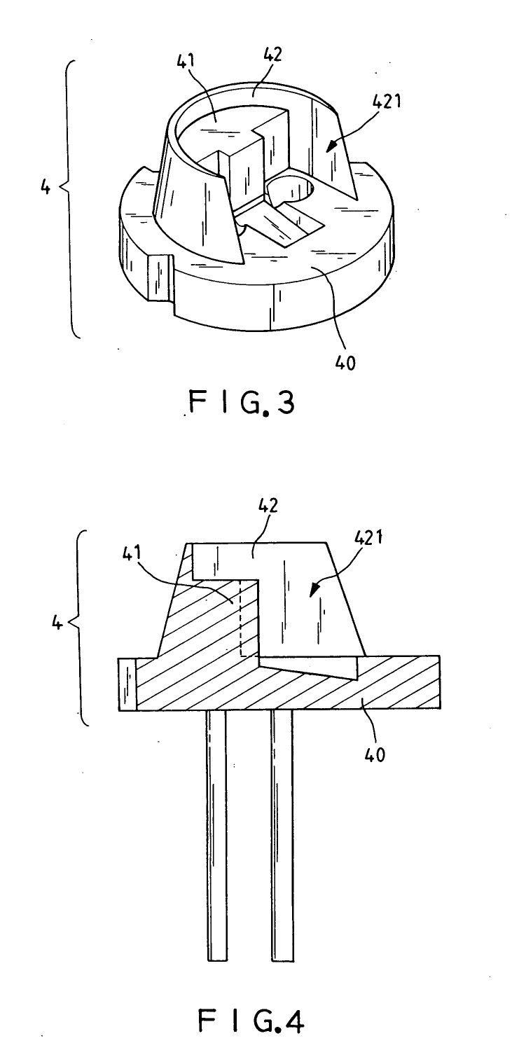

First of all, referring to FIGS. 3 and 4, a packaging base for semiconductor elements in accordance with the invention is made of metal powder selected from the group consisting of cupper (Cu), iron (Fe), tungsten (W), molybdenum (Mo), aluminum (Al), indium (In), and gallium (Ga) or from an alloy of combinations thereof. A heat sink 40 is integrally formed by metallurgical injection molding process. A fixing mount 41 and a protection mount 42 are positioned on the heat sink 40, thereby creating a packaging base structure 4. The protection mount 42 surrounds the fixing mount 41 for protecting semiconductor elements like laser diode dies. The packaging base structure 4 includes a mounting gap 421 for the purpose of an easy installation of the semiconductor elements. Moreover, the packaging base structure 4 is also suitable for packaging high power electronic elements and light-emitting elements.

Based on the above-mentioned configuration, the packaging base structure 4 in accordance with the invention is integrally formed, thereby saving the assembly process among elements. In this way, the fabricating process can be simplified. Moreover, the conventional thermal contact resistance between the heat sink 40 and the fixing mount 41 can be avoided for enhancing the heat-removal capacity. By selecting different metal powder or adjusting the alloy proportion, the thermal expansion coefficient of the packaging base structure 4 can be changed as well, thereby meeting different product requirements. Therefore, the packaging base for semiconductor elements in accordance with the invention can increase the heat-removal capacity and simplify the fabrication process.

Many changes and modifications in the above-described embodiment of the invention can, of course, be carried out without departing from the scope thereof. Accordingly, to promote the progress in science and the useful arts, the invention is disclosed and is intended to be limited only by the scope of the appended claims.

What is claimed is:

1. A packaging base for semiconductor elements made of metal powder by metallurgical injection molding process, a heat sink being integrally formed thereon, a fixing mount and a protection mount being positioned on the heat sink, the protection mount surrounding the fixing mount, the packaging base structure further having a mounting gap.

2. The packaging base for semiconductor elements s recited in claim 1 wherein the metal powder is selected from the group consisting of cupper (Cu), iron (Fe), tungsten (W), molybdenum (Mo), aluminum (Al), indium (In), and gallium (Ga) or from an alloy of combinations thereof.

3. The packaging base for semiconductor elements as recited in claim 1 wherein the packaging base structure integrally formed is suitable for packaging the laser diodes.

4. The packaging base for semiconductor elements as recited in claim 1 wherein the packaging base structure integrally formed is suitable for packaging the high power electronic elements.

5. The packaging base for semiconductor elements as recited in claim 1 wherein the packaging base structure integrally formed is suitable for packaging the light-emitting elements.
